(19) United States
(12) Patent Application Publication
(10) Pub. No.: US 2005/0157475 A1
(43) Pub. Date: Jul. 21, 2005

(54) Method of making printed circuit board with electroplated conductive through holes and board resulting therefrom

(75) Inventor: Robert D. Edwards, Binghamton, NY (US)

Correspondence Address: Lawrence R. Fraley, IP Law Counsel;Endicott Interconnect Technologies, Inc., FBU/257-2 AA12, 1701 North Street, Endicott, NY, 13760, US

(73) Assignee: Endicott Interconnect Technologies, Inc., Endicott, NY (US)

(21) Appl. No.: 10/757,586

(22) Filed: Jan. 15, 2004

(51) Int. Cl. H05K 1/00; C25D 5/02

(52) U.S. Cl. 361/748; 205/131

(57) ABSTRACT

A method of electrolytically plating a layer of metal on the internal surface of an opening within a substrate so as to deposit a substantially uniform layer of metal on the internal surface of the opening. The method comprises substantially immersing a substrate having an opening therein within an electroplating bath containing ions of a metal to be deposited onto the internal surface of the opening and passing an electric current through the bath wherein the current includes modulated forward and reverse pulses, selected ones of the forward and/or reverse pulses followed by a pause in the electric current. A printed circuit board produced using this method is also provided.

### TECHNICAL FIELD

This invention relates to printed circuit boards and particularly to multilayered printed circuit boards having a plurality of conductive through holes therein.

### BACKGROUND OF THE INVENTION

The manufacture of printed circuit boards (sometimes referred to as printed wiring boards) has resulted in the need to provide large numbers of conductive openings or holes therein, e.g., to connect printed circuitry on both sides of the board's substantially planar rigid or flexible insulating substrate. Of increased importance is the manufacture of multilayer printed circuit board structures, the most common boards sold today in view of increased operational demands for the products in which such boards are utilized. Such boards typically include several parallel, planar, alternating inner layers of insulating substrate material and conductive metal. The exposed outer sides of the laminated structure are typically provided with circuit patterns, and the metal inner layers typically also contain circuit patterns, except in the case of internal power planes which are substantially solid, albeit also often containing clearance openings or other openings if desired.

In double-sided and multilayer printed circuit boards, it is necessary to provide conductive interconnections between the various conductive layers or sides of the board. This is commonly achieved by providing the aforementioned openings or holes in the form of metallized, conductive thru-holes in the board which communicate with the sides and layers requiring electrical interconnection. For some applications, it is desired that electrical connection be made with all of the conductive layers. In such a case, thru-holes are also typically provided through the entire thickness of the board. For these, as well as other applications, it is also often desired to also provide electrical connection between the circuitry on one face of the board and one or more of the inner circuit layers. In those cases, “blind vias”, passing only part way through the board are provided. In still another case, such multilayered boards often require internal “vias” which are located entirely within the board's structure and covered by external layering, including both dielectric and conductive. Such internal “vias” are typically formed within a sub-part structure of the final board and then combined with other layers during final lamination of the board. For purposes of this disclosure, the term “thru-hole” is meant to include thru-holes that pass entirely through the board (also referred to in the printed circuit field as plated-through-holes or PTHs), “blind vias” which extend from an external surface of the board into a specified conductive layer of the board, as well as “internal vias” which are internally “captured” by the board's outer layers (as a result of subsequent addition of such layers during board build-up.

To provide the desired circuit pattern on the board, the art has developed a variety of manufacturing sequences, many of which fall into the broad categories of “subtractive” or “additive” techniques. Common to subtractive processes is the need to etch away (or subtract) metal to expose substrate surface in areas where no circuitry is desired. Additive processes, on the other hand, begin with exposed substrate surfaces (or thin commoning metallization layers for additive electroplate) and build up thereon of metallization in desired areas, the desired areas being those not masked by a previously-applied pattern of plating resist material (e.g., called photoresist in the printed circuit board field).

Typically, thru-holes are drilled (including mechanically or more recently using lasers) or punched into or through the board at desired locations. Drilling or punching provides newly-exposed surfaces including via barrel surfaces and via peripheral entry surfaces. The dielectric substrate, comprising a top surface, a bottom surface, and at least one exposed via hole surface, consisting partly or entirely of insulating material, is then metallized, generally by utilization of electroless or electroplating metal deposition procedures.

Although conventional techniques have generally been successful in the manufacture of printed circuit boards having relatively close (dense) wiring and thru-hole pattern configurations, recent design requirements have called for even more dense configurations. As an example, the increase in the number of chips mounted on a board (one or more of same usually contained within a “module” or the like component surface or otherwise mounted on the board) has resulted in a corresponding increase in the needed interconnections. Examples of products having such increased demands include workstations, high-end servers, more advanced computers and similar products in the information handling (computing) field. Consequently, the thru-holes that interconnect the layers in the boards (one common example is referred to a “back panel”) may become longer and/or deeper without increasing in diameter. Such boards typically include an overall thickness of from about 120 mils (thousandths) to about 400 mils, and the smallest thru-holes (e.g., PTHs) in such boards may have a diameter within the range of from about 8 mils to about 26 mils. The ratio of length to diameter (or to one transverse dimension if the hole or cavity is not of circular cross-section) is commonly referred to as the thru-hole's “aspect ratio”. Yet another version of an “aspect ratio” is that which defines the ratio of the board's ultimate thickness to that of the thru-hole diameter. For purposes of this invention, this is referred to as the board-hole “aspect ratio.”

Boards of the type defined herein may be processed according to the teachings of this invention across a wide range of board thicknesses, from about 90 mils to about 400 mils with varied holes sizes. The greatest benefit of the invention versus standard techniques will be seen when the hole diameters relative to the board thickness exceed an aspect ratio of about 10:1 and extend as high as about 25:1, the smallest holes ranging from about 8 mils to about 26 mils. Accordingly, all combinations of the range of hole sizes and board diameters are not possible; holes of 8 mil diameter, for example, are typically not possible in 400 mil thick boards, but for any given board thickness, larger hole diameters will be easier to process. More specifically, the following represents examples of successfully utilized hole diameters with comparative thicknesses usable in this invention:

| Hole Dia.(mils) | Board Thickness (mils) |
|---|---|
| 10 | 210 |
| 16 | 260 |
| 26 | 380 |

The present invention deals specifically with electrolytic plating of thru-holes of this type. In such an electroplating process, the interior of the thru-holes in the circuit board has frequently relied on chemical additives to the plating bath that promote uniform deposition of the desired metal(s). The ability of a bath or component thereof to promote uniform deposition of metal in holes, recesses, and the like is known in the printed circuit board art as the bath's “throwing power”. As described in greater detail below, it is known that the use of pulsed current electrolytic waveforms may, in some cases, enhance the plating of metal in the interior of thru-holes. In one example, use of a waveform having a long cathodic (forward) pulse followed by a short anodic (reverse) pulse has been found to be useful in plating the interior surfaces of holes of conventional circuit boards having hole diameters larger than about 12 mils, providing thru-hole aspect ratios typically of about 6:1, but sometimes as high as about 10:1. It has also been found that when such a waveform is used, uniform plating may be achieved when conventional additives such as levelers and brighteners are omitted from the bath. Related to this, it has also been discovered to utilize a combination of both positive (forward, or electrodeposition) and negative (reverse or electrodissolution) current densities, each of substantially square waveforms, in a conventional acid bath formulation of relatively high copper concentrations, e.g., around 16 to 25 grams per liter (g/l), including known brighteners, levelers and carriers. This procedure, known as periodic reverse pulse plating (PRP) has found acceptance by some printed circuit board manufacturers, including the assignee of the present invention. The forward current densities in the PRP plating used to process conventional boards typically range from 15 to 30 amperes per square foot (amperes per square foot) for a duration of typically 10 to 30 milliseconds (ms). The corresponding reverse electrodissolution (or stripping) densities range from a much higher 30 to 90 amperes per square foot for a duration typically of only about 1 ms. Accordingly, the reverse to forward current density ratios range from 2:1 to 3:1 in such a process, or, alternatively spoken, the forward to reverse density ratios range from 1:2 to 1:3.

Plating of such aspect ratio thru-holes has presented problems in achieving uniform deposition of metal both on the surface of the board (if plated simultaneously with the holes, as is often employed) and, of course, within the holes themselves. Such problems are recognized when attempting to utilize PRP plating. One method of plating such holes using defined pulse waveforms has been discussed in U.S. Pat. No. 6,210,555, to Taylor et al. In addition, the use of pulsed plating is also described in published patent applications U.S. 2003/0019755 to Hey et al and in U.S. 2003/0075450 to Taylor et al. The entire disclosures of these three documents are incorporated herein by reference. As discussed specifically in U.S. Pat. No. 6,210,555, and as found when utilizing conventional PRP plating, surfaces located within small recesses, cavities and holes of highly dense hole pattern configurations can be hydrodynamically inaccessible to the supply of ionically dissolved metals within the plating bath. For example, the central region of the holes, i.e., the region approximately equidistant from either surface of the board or from its upper “land” to its lower “land” in the case of a hole (e.g., the aforementioned “internal via”) which eventually will be internally located within a larger board thickness, may receive a thinner deposit of metal, e.g., be lightly plated, or, in extreme cases, may receive no metal at all at some locations in this region. A thru-hole having such a metal deposit on its internal surface obviously provides a poor electrical connection between the conductive surfaces and/or internal conductive layers of the circuit board. Furthermore, even if the central region of the hole receives some metal deposit, it may not be strong enough to resist the mechanical stresses imposed by further processing of the board. In particular, if the plating in the center of the hole is too thin or has poor mechanical properties, it may crack circumferentially when the board is subjected to elevated temperatures such as when solder is applied to the surfaces of the board. Such “heat shock” or “solder shock” may cause the board to expand enough to break the layer of metal at its thinnest (and weakest) location(s). Such a “barrel crack” may in turn cause the electrical connection to be broken, with the result that the board fails. Even if electrical contact through the plated hole having such a crack is maintained when inspected at room temperature, the contact may be broken when the temperature of the board becomes elevated during final prolonged utilization thereof in its final destination.

As indicated above, providing a coating of metal in thru-holes has been accomplished by utilizing chemical additives, e.g., levelers, and the like, to the plating bath, and by conducting the plating at specified current densities, e.g., the aforementioned PRP plating process. However, as mentioned, such methods, including the PRP process, have proven inadequate when attempting to adequately plate with sufficient uniformity of thickness the internal walls of thru-holes of a highly dense configuration as demanded today.

Accordingly, there exists a need to provide an improved method of metallizing the internal surfaces of thru-holes using electrolytic plating in order to satisfy the increasingly high demands of today's printed circuit board industry wherein such a method will overcome the drawbacks mentioned above and others known in the industry. The present invention provides such a method (and resulting product) and is thus believed to represent a significant advancement in the art.

### DESCRIPTION OF THE INVENTION

It is, therefore, a primary object of the present invention to enhance the printed circuit board art by providing a new and unique method of producing such boards.

It is another object of the invention to provide such a process and resulting board in which several conductive thru-holes are formed utilizing PRP plating.

It is still another object of the invention to provide such a process which can be implemented using conventional printed circuit board technologies and thus performed with little or no increased cost over conventional techniques.

According to one aspect of the invention, there is provided a method of electrolytically plating a layer of metal on the internal surface of an opening within a substrate, the method comprising substantially immersing a substrate having an opening therein within an electroplating bath containing ions of a metal to be deposited onto the internal surface of the opening and passing an electric current through the bath wherein the current includes modulated forward and reverse pulses, selected ones of the forward and/or reverse pulses followed by a pause in the electric current, so as to deposit a substantially uniform layer of metal on the internal surface of the opening.

According to another aspect of the invention, there is provided a multilayered printed circuit board comprising a dielectric substrate having a predetermined thickness and at least one conductive, substantially uniformly plated opening within the substrate, the plated opening formed using an electrolytic plating operation in which an electric current including modulated forward and reverse pulses is passed through a bath including ions of the metal to form the plating therein with selected ones of the forward and/or reverse pulses followed by a pause in the electric current, so as to deposit a substantially uniform plating of metal on the internal surface of the opening while the dielectric substrate is substantially immersed within the bath.

### BRIEF DESCRIPTION OF THE DRAWING

FIG. 1 is a waveform pattern of modulated forward-reverse current used to metallize thru-holes in printed circuit boards according to one embodiment of the invention; and

FIG. 2 is a partial, side elevational view, in section, of a printed circuit board made using the teachings of the invention.

### BEST MODE FOR CARRYING OUT THE INVENTION

For a better understanding of the present invention, together with other and further objects, advantages and capabilities thereof, reference is made to the following disclosure and appended claims in connection with the above-described drawings.

It has been discovered, quite surprisingly, that the utilization of a pause following the application of forward and/or reverse pulses during what is referred to as a periodic reverse plating (PRP) process, in combination with other parameters as defined herein, has resulted in the application of uniformly thick plated layers (e.g., copper) on the internal surfaces of openings within a substrate such as that to be used in a printed circuit board. Accordingly, the invention provides a new and unique procedure for providing such uniform platings in such openings as such thru-holes of the type defined herein (those utilized in printed circuit boards). However, the invention is not limited to the mere plating of printed circuit board substrates but instead is applicable to plating of other substrates wherein a uniform thickness is essential for proper utilization thereof. As will be defined herein, when using the teachings of the invention, it is possible to utilize lower concentrations of the metal in the bath and thus various other components (e.g., brighteners) of the bath as well. Of further significance, the teachings of the invention result in the utilization of substantially reduced average amperes per square foot per bath plating to thus reduce the currents required and add another cost advantage to the invention. In one embodiment, the invention preferably utilizes a bath including brighteners, carriers and/or levelers.

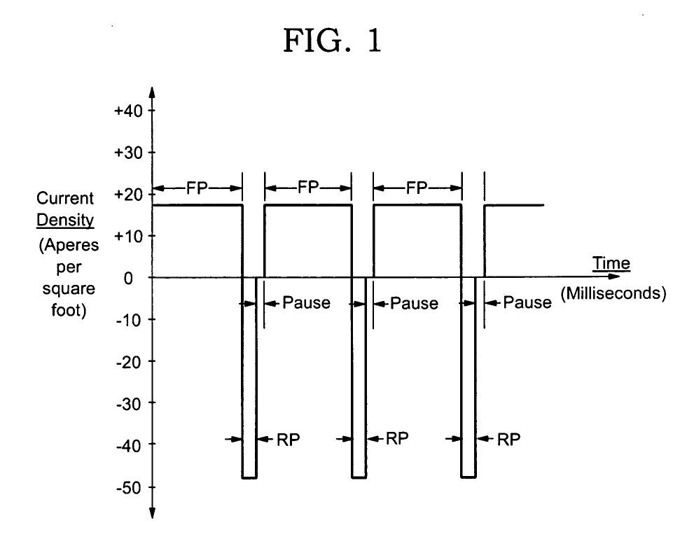

FIG. 1 is a schematic representation of a rectangular modulated pattern of waveforms used in the process of the present invention. FIG. 1 illustrates three complete waveforms, comparing the relative current densities (amperes per square foot) versus time (milliseconds). Each waveform in FIG. 1 includes a forward (cathodic) pulse FP followed by a reverse (anodic) pulse RP. Although each waveform is shown as comprising two rectangular pulses, this is not meant to limit the invention because these pulses need not be rectangular and may have a different profile. In the discussion herein, rectangular pulses will be described for simplicity purposes.

Significantly, in FIG. 1, each forward pulse and reverse pulse waveform is followed by a brief pause prior to initiation of the second forward pulse-reverse pulse waveform. Following this second waveform, a second pause is then initiated and current subsequently applied to produce the third, illustrated, waveform. Although FIG. 1 illustrates the use of a pause immediately following the reverse pulse RP, it is within the scope of the invention to provide this pause immediately following the forward pulse FP and prior to the reverse pulse which would then be instantly followed by the subsequent forward pulse. It is also within the scope of the invention to provide a brief pulse following both the forward and reverse pulses in each waveform. The unique teachings of the invention result from utilization of any of the above possibilities. For purposes of simplification, however, the pauses are shown as following the reverse pulses.

In FIG. 1, forward pulses within the range of from about 40 to about 140 milliseconds may be utilized followed by reverse pulses within the range of from about 2 to about 8 milliseconds in duration. The desired pause following the reverse pulse is preferably only from about 0.1 to about 1.0 millisecond. The preferred ratio of times of the forward pulse to reverse pulse pause to pause time is within the range of from about 40:4:1 to about 400:20:1. The respective current density for the forward pulses is preferably only about 16 amperes per square foot while each of the reverse pulses possess a current density of about negative 48 amperes per square foot. Significantly, the result of this application of current density and time produces an average current density of only from about 8 to about 15 amperes per square foot. Utilizing the above densities, the ratio of such densities of the forward pulses to the reverse pulses is within the range of from about 1:2.5 to about 1:3.5. Thus it is seen that the forward, cathodic pulses are relatively long in time duration in comparison to the relatively short reverse, anodic pulses. It is further seen that the extremely brief pause is, by comparison, far less in proportion than the corresponding forward and reverse pulses, while still assuring the uniform plating taught herein. Utilizing the above teachings, plating thickness of from about 0.5 mils to about 2.0 mils were successfully achieved in printed circuit boards having overall thicknesses of from about 90 mils to about 400 mils. The thru-holes (described further below) successfully plated using the teachings of the invention may possess diameters within the range of from about 8 mils to about 26 mils.

Of further significance, the current applied using the waveform in FIG. 1 was applied to a bath including organic brighteners, carriers and/or levelers known in the electrolytic plating art for use in printed circuit board plating. As stated, however, it was possible using the teachings of the invention to reduce the quantities (percentages) of selected ones (e.g., brighteners) of such additional components and still successfully achieve uniform plating. By way of example, plating a substrate having the above dimensions using an acid bath composition was possible wherein the bath only included from about 10 to about 15 grams per liter of copper. Furthermore, the bath composition included from about 230 to about 270 grams per liter of acid, a preferred acid being sulfuric. The resulting substrate plated when immersed in a bath and applying the above current densities and times produced a substrate wherein the ratio of the substrate thickness to the thru-hole diameter was within the range of from about 8:1 to about 25:1, which is considered very desirable for the highly dense thru-hole patterns demanded in today's more complex printed circuit boards such as those mentioned above for use in servers, back panels and the like.

In one example, a board having a thickness of about 210 mils with about 10 mil thru-holes was successfully plated and the substrate was immersed in the bath with the current applied for a period of about 200 minutes.

The above results contrast sharply to known PRP processing as used on printed circuit boards. Such known processing has typically utilized a forward pulse of only about 10-30 milliseconds followed by a reverse or stripping pulse of 0.5 to 1.5 milliseconds. The typical acid copper bath formulation utilized for this electrolytic plating process required relatively high copper concentrations, usually at least 20 grams per liter, but always greater than 16 grams per liter. The invention thus represents a significant improvement to these requirements, particularly through the utilization of less copper and lower current densities. (The forward current densities in known PRP processing are typically from 16 to 30 amperes per square foot with reverse densities as high as 90 amperes per square foot.)

In one example of the invention, the bath composition utilized to successfully plate thru-holes included the following components, among others, in associated percentages by weight:

| | | |
|---|---|---|
| Copper | 1.1% | wt. |
| Sulfuric Acid | 21% | wt. |
| Chloride | 0.006% | wt. |
| Brightener Solution | 0.013% | wt. |
| Suppressor Solution | 3.4% | wt. |
| Water (Approx.) | 74.5% | wt. |

The frequency of the pulse train (each waveform) may range from about 6 Hz to about 24 Hz, and is preferably from about 9 Hz to about 16 Hz. As stated, the substrate is immersed in the plating bath above for the defined time period and the appropriate electrical field established between the substrate (as one electrode) and anodes, soluble or insoluble and controlled as indicated above.

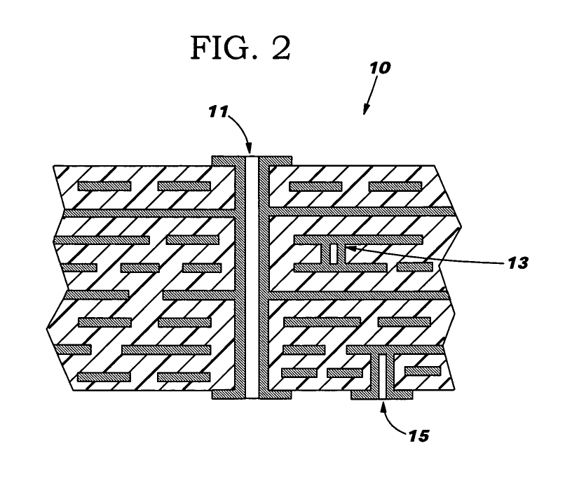

In FIG. 2, there is seen a printed circuit board 10 made utilizing the teachings of the invention. Board 10 preferably comprises a plurality of individual conductive (e.g., copper) layers containing several thru-holes therein. Examples of such thru-holes include a PTH 11 which, as defined above, extends entirely through the board thickness, an internal “via” 13 (which is preferably formed in an individual dielectric layer having two conductive layers on opposite sides thereof, this subcomposite then laminated together with other dielectric and conductive layers to form the structure in FIG. 2), and a blind “via” 15 which extends from an outer surface of the board to a predetermined (blind) depth within the board structure. As seen in FIG. 2, a total of eight internal conductive layers are utilized, but this is not meant to limit the invention in that several additional layers (or even fewer) may be utilized. As seen in FIG. 2, selected ones of the internal layers are directly electrically coupled to the PTH 11, thus assuring that any component, e.g., a module as cited above, coupled to the PTH (e.g., through a pin inserted therein) will be connected to these desired internal layers. The configuration depicted in FIG. 2 is representative only and not meant to limit the invention in that several other various combinations of layers and thru-holes are readily possible.

In the embodiment of FIG. 2, it was also possible to plate the blind “vias” 15 simultaneous with plating of the PTHs. Of course, the internal “vias” 13 require plating prior to subsequent board lamination. Significantly, the teachings of this invention are applicable to such previous plating of thinner substrates for such eventual incorporation within a larger, multi-layered structure.

In one example of the invention, a substrate comprised of a dielectric material selected from the group consisting of fiberglass-reinforced epoxy resin (also known in the art as “FR4”), polytetrafluoroethylene, polyimide, polyamide, cyanate resin, photoimageable materials and combinations thereof was utilized. The specific example described above utilized a dielectric substrate of fiberglass-reinforced epoxy resin.

Thus there has been shown and described a new and unique method of plating high density, relatively small diameter thru-holes in a substrate such as a printed circuit board dielectric substrate to provide uniform plating on the thru-holes which is sufficient to provide a sound, effective electrical connection to the various layers and/or components within and mounted on the circuit board, respectively. The teachings herein are considered particularly significant due to the resulting use of significantly lower average current densities and compositions with less of the desired metal needed for forming the layer deposited on the thru-hole opening internal surfaces. Other significant advantages are readily discernible from the foregoing description.

While there have been shown and described what are at present the preferred embodiments of the invention, it will be obvious to those skilled in the art that various changes and modifications may be made therein without departing from the scope of the invention as defined by the appended claims.

1. A method of electrolytically plating a layer of metal on the internal surface of an opening within a substrate, said method comprising:
substantially immersing a substrate having an opening therein within an electroplating bath containing ions of a metal to be deposited onto the internal surface of said opening; and
passing an electric current through said bath wherein said current includes modulated forward and reverse pulses, selected ones of said forward and/or reverse pulses followed by a pause in said electric current, so as to deposit a substantially uniform layer of said metal on said internal surface of said opening.

2. The method of claim 1 wherein said substrate is a dielectric substrate for use in a printed circuit board and said opening is a conductive thru-hole.

3. The method of claim 2 wherein said dielectric substrate is a material selected from the group consisting of from the group consisting of fiberglass-reinforced epoxy resin, polytetrafluoroethylene, polyimide, polyamide, cyanate resin, photoimageable materials and combinations thereof.

4. The method of claim 3 wherein said metal is copper.

5. The method of claim 1 wherein said forward pulses each have a pulse width within the range of from about 40 to about 140 milliseconds.

6. The method of claim 5 wherein said reverse pulses each have a pulse width within the range of from about 2 to about 8 milliseconds.

7. The method of claim 6 wherein said pause in said electric current following said selected ones of said forward and/or reverse pulses is within the range of from about 0.1 to about 1.0 millisecond.

8. The method of claim 7 wherein the ratio of times of said forward pulse to said reverse pulse to said pause is within the range of from about 40:4:1 to about 400:20:1.

9. The method of claim 1 wherein each of the pairs of said forward and reverse pulses are provided for an average current density of from about 8 to about 15 amperes per square foot.

10. The method of claim 9 wherein the ratio of said current densities of said forward pulses to said reverse pulses is within the range of from about 1:2.5 to about 1:3.5.

11. The method of claim 1 wherein said electroplating bath further includes organic brighteners, carriers and/or levelers.

12. The method of claim 1 wherein said electroplating bath is an acid bath composition including from about 10 to about 15 grams per liter of copper.

13. The method of claim 12 wherein said acid bath composition includes from about 230 to about 270 grams per liter of acid.

14. The method of claim 12 wherein said acid is sulfuric acid.

15. The method of claim 1 wherein said substrate has a predetermined thickness and said opening has a predetermined diameter, the ratio of said predetermined thickness of said substrate to said predetermined diameter of said opening being within the range of from about 8:1 to about 25:1.

16. A printed circuit board comprising:
a dielectric substrate having a predetermined thickness; and
at least one conductive, substantially uniformly plated opening within said substrate, said plated opening formed using an electrolytic plating operation in which an electric current including modulated forward and reverse pulses is passed through a bath including ions of the metal to form said plating therein with selected ones of said forward and/or reverse pulses followed by a pause in said electric current, so as to deposit a substantially uniform plating of said metal on the internal surface of said opening while said dielectric substrate is substantially immersed within said bath.

17. The printed circuit board of claim 16 wherein said dielectric substrate is of a dielectric material selected from the group consisting of fiberglass-reinforced epoxy resin, polytetrafluoroethylene, polyimide, polyamide, cyanate resin, photoimageable materials and combinations thereof.

18. The printed circuit board of claim 16 wherein said metal forming said conductive, substantially uniformly plated opening comprises copper.
